(19) United States
(12) Patent Application Publication
(10) Pub. No.: US 2016/0293252 A1
(43) Pub. Date: Oct. 6, 2016

(54) SEMICONDUCTOR STORAGE DEVICE

(71) Applicant: KABUSHIKI KAISHA TOSHIBA, Tokyo (JP)

(72) Inventors: Ryu OGIWARA, Yokohama Kanagawa (JP); Daisaburo TAKASHIMA, Yokohama Kanagawa (JP)

(73) Assignee: KABUSHIKI KAISHA TOSHIBA, Tokyo (JP)

(21) Appl. No.: 14/848,279

(22) Filed: Sep. 8, 2015

Related U.S. Application Data
(60) Provisional application No. 62/140,059, filed on Mar. 30, 2015.

(51) Int. Cl. G11C 13/00

(52) U.S. Cl. CPC G11C 13/0004; G11C 13/004; G11C 13/0069; G11C 13/0038; G11C 2013/0054

(57) ABSTRACT

According to one embodiment, a semiconductor storage device includes: a first memory cell; a first bit line coupled to the first memory cell; and a first circuit applying a first voltage to the first bit line in a write operation for the first memory cell. The first voltage has no temperature dependence at temperatures lower than or equal to a first temperature, and has a negative temperature dependence at temperatures higher than the first temperature.

### CROSS-REFERENCE TO RELATED APPLICATIONS

This application claims the benefit of U.S. Provisional Application No. 62/140,059, filed Mar. 30, 2015, the entire contents of which are incorporated herein by reference.

### FIELD

Embodiments described herein relate generally to a semiconductor storage device.

### BACKGROUND

In recent years, an interfacial phase change memory (iPCM) is developed as one of new semiconductor storage devices. In an iPCM, a crystalline state of a variable resistance element is subjected to a phase change by applying a voltage thereto. By this phase change, the variable resistance element is brought into a low-resistance state or a high-resistance state, and stores data therein on the basis of these two states.

In all the resistance random access memories including the iPCM, a magnetic random access memory (MRAM), such as a memory changing in phase between an amorphous phase and crystalline phase, and the like, realization of a method and circuit for optimizing a voltage and current necessary for a phase change with respect to a surrounding environmental temperature is desired.

### BRIEF DESCRIPTION OF THE DRAWINGS

FIG. 1 is a block diagram showing the overall configuration of a semiconductor storage device of a first embodiment;

FIG. 2 is a circuit diagram of a Vset generator included in the semiconductor storage device of the first embodiment;

FIG. 3 is a graph showing temperature dependence of a set voltage in the semiconductor storage device of the first embodiment;

FIG. 4 is a graph showing a relationship between a voltage to be applied to a variable resistance element included in the semiconductor storage device of the first embodiment and phase change;

FIG. 5 is a circuit diagram of an Irst generator included in a semiconductor storage device of a second embodiment;

FIG. 6 is a graph showing temperature dependence of a reset current in the semiconductor storage device of the second embodiment;

FIG. 7 is a graph showing temperature dependence of a voltage of a bit line BL, and reference voltage Vref at the time of read in a semiconductor storage device in a third embodiment;

FIG. 8 is a circuit diagram of a Vset generator included in a semiconductor storage device of a fourth embodiment;

FIG. 9 is a graph showing temperature dependence of a resultant current of a BGR circuit having no temperature dependence, and BGR circuit having negative temperature dependence in the semiconductor storage device of the fourth embodiment;

FIG. 10 is a circuit diagram of a Vset generator included in a semiconductor storage device of a fifth embodiment;

FIG. 11 is a circuit diagram of a Vset generator included in a semiconductor storage device of a sixth embodiment;

FIG. 12 is a block diagram showing a modification example of a memory cell array included in the semiconductor storage device of the first embodiment; and

FIG. 13 is a graph showing a modification example of temperature dependence of the set voltage in the semiconductor storage device of the first embodiment.

### DETAILED DESCRIPTION

Hereinafter, semiconductor storage devices of the embodiments will be described with reference to the drawings. In the following descriptions, constituent elements having an identical function and configuration are denoted by identical reference symbols, and duplicated descriptions are given only when necessary. Further, the following embodiments exemplify devices and methods for realizing the technical ideas of the embodiments, and are not intended to limit the material, shape, structure, arrangement, and the like of the constituent parts to those in the following.

In general, according to one embodiment, a semiconductor storage device includes: a first memory cell; a first bit line coupled to the first memory cell; and a first circuit applying a first voltage to the first bit line in a write operation for the first memory cell. The first voltage has no temperature dependence at temperatures lower than or equal to a first temperature, and has a negative temperature dependence at temperatures higher than the first temperature.

In the following embodiments, descriptions will be given by taking an interfacial phase change memory (iPCM) as an example of a semiconductor storage device.

### 1. First Embodiment

A semiconductor storage device of a first embodiment will be described below.

### 1.1 Overall Configuration of Semiconductor Storage Device

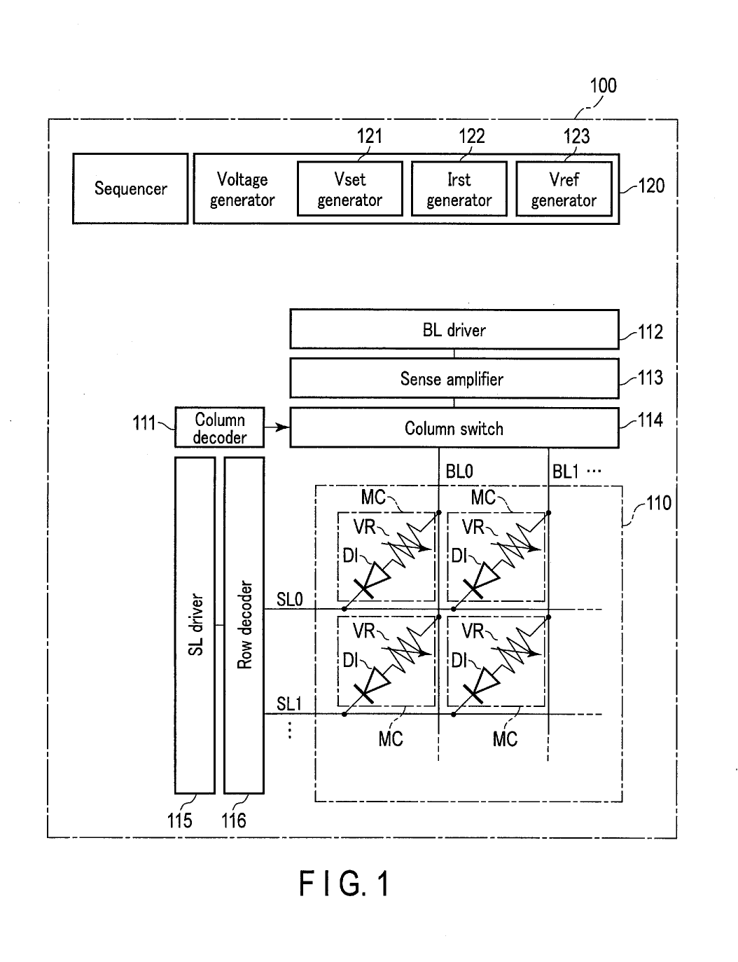

FIG. 1 is a block diagram showing the overall configuration of the semiconductor storage device of the first embodiment. The semiconductor storage device 100 of this embodiment includes a memory cell array 110, column decoder 111, bit-line driver 112, sense amplifier 113, column switch 114, source-line driver 115, row decoder 116, voltage generator 120, and sequencer 130.

The memory cell array 110 includes a plurality of memory cells MC arranged on a semiconductor substrate in a matrix form. It should be noted that the number of the memory cells MC is arbitrary. Memory cells arranged on the same column are connected to a certain bit line BLk (k is an integer greater than or equal to 0) as a common connection. Further, memory cells arranged on the same row are connected to a certain source line SLm (m is an integer greater than or equal to 0) as a common connection. A memory cell MC includes a variable resistance element VR, and a diode DI connected in series. The variable resistance element VR is connected to a bit line BL at one end thereof, and is connected to an anode of the diode DI at the other end thereof. In the diode DI, a cathode thereof is connected to a source line SL. The variable resistance element VR in this embodiment constitutes a super lattice including, for example, germanium Ge, tellurium Te, and antimony Sb, and a germanium-tellurium layer, and an antimony-tellurium layer are laminated therein. The super lattice is brought into a low-resistance state or a high-resistance state according to a change in crystalline state. More specifically, when, for example, a necessary voltage pulse is applied to the super lattice, germanium atoms Ge in the super lattice move to change the bonding state of the germanium atoms Ge and tellurium atoms Te. An element having such characteristics is defined as a super lattice phase-change element. In the following description, a change in crystalline state of the variable resistance element is called a “phase change”, a state where the variable resistance element VR is in a low-resistance state is called a “set state”, and a state where the variable resistance element VR is in a high-resistance state is called a “reset state”. It should be noted that the diode DI shown in FIG. 1 may be replaced with a diode-connected transistor.

The column decoder 111 decodes a column address to obtain a column address decoded signal.

The column switch 114 selects one of the bit lines BL on the basis of the column address decoded signal, and connects the selected bit line BL to the sense amplifier 113.

The bit-line driver 112 applies voltages necessary for read and write operation, for example, to the sense amplifier 113.

In the read operation, the sense amplifier 113 senses the data read from a memory cell MC onto a bit line BL. Also, in the write operation, the sense amplifier 113 applies voltages corresponding to the write data to a memory cell MC. These voltages are given from the bit-line driver 112.

The source-line driver 115 applies voltages necessary for read, write, and erasure operation to the row decoder 116.

The row decoder 116 selects one of the source lines SL on the basis of a row address decoded signal obtained by decoding a row address. Further, the row decoder 116 applies an appropriate voltage to each of a selected source line SL and unselected source lines SL.

The voltage generator 120 generates voltages and currents necessary for read, write, and erasure operation by raising or lowering a power-supply voltage VDD to be applied from outside, and supplies the generated voltages and currents to, for example, the bit-line driver 112, source-line driver 115 or the like. More specifically, the voltage generator 120 includes a Vset generator 121, Irst generator 122, and Vref generator 123. The Vset generator 121 generates a set voltage Vset needed to make the variable resistance element VR carry out a phase change, and bring the variable resistance element VR into the set state. The Irst generator 122 generates a reset current Irst needed to make the variable resistance element VR carry out a phase change, and bring the variable resistance element VR into the reset state. The Vref generator 123 generates a reference voltage Vref needed, for example, at the time of the read operation.

The sequencer 130 controls operations of the whole semiconductor storage device 100.

### 1.2 Configuration of Vset Generator

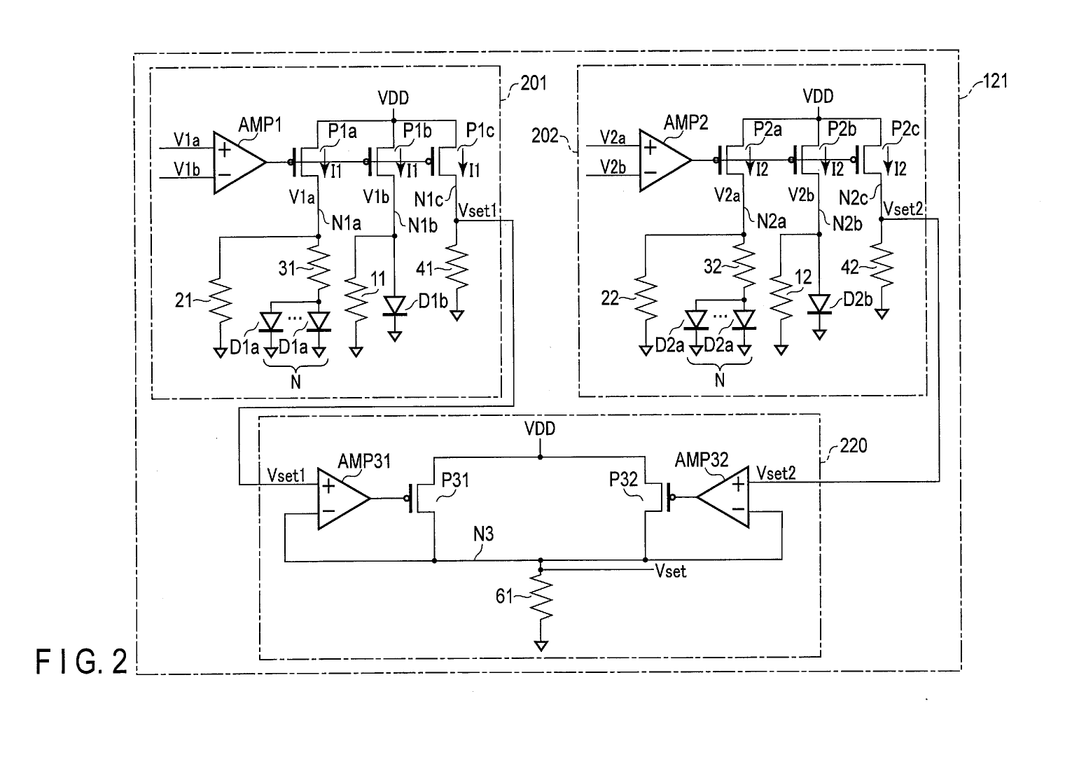

FIG. 2 is a circuit diagram of the Vset generator 121. The Vset generator 121 of this embodiment includes bandgap reference (BGR) circuits 201 and 202, and a voltage selection circuit 220.

The configuration of each of the BGR circuits is described in, for example, H. Banba, H. Shiga, A. Umezawa, T. Miyaba, T. Tanzawa, S. Atsumi, and K. Sakui, “A CMOS Bandgap Reference Circuit with Sub-1-V Operation” IEEE JOURNAL OF SOLID-STATE CIRCUITS VOL., 34, NO. 5, MAY 1999. The whole of this literature is incorporated herein as a reference.

First, the configuration of each of the BGR circuits 201 and 202 will be described below.

The BGR circuit 201 includes an operational amplifier AMP1, p-channel MOS transistors P1a, P1b, and P1c, resistance elements 11, 21, 31, and 41, N (N is an integer greater than or equal to 2) diodes D1a, and diode D1b.

The diodes D1a and the diode D1b have the same current-voltage characteristics. In the operational amplifier AMP1, a voltage V1a of a node N1a is input to a non-inverting input terminal, a voltage V1b of a node N1b is input to an inverting input terminal, and an output terminal is connected to gates of the transistors P1a, P1b, and P1c as a common connection.

The transistors P1a, P1b, and P1c have the same transistor size (for example, a gate width and/or a gate length, and the like). In the transistors P1a, P1b, and P1c, their sources are connected to a power supply node applying a power-supply voltage VDD as a common connection, and their drains are connected to the node N1a, node N1b, and a node N1c, respectively.

The N diodes D1a are connected in parallel with each other, and their cathodes are grounded.

The resistance element 21 is connected to the node N1a at one end thereof, and is connected to the ground node (is grounded) at the other end thereof. The resistance element 31 is connected to the node N1a at one end thereof, and is connected to anodes of the diodes D1a as a common connection. The resistance element 11 is equal to the resistance element 21 in resistance value, is connected to the node N1b at one end thereof, and is grounded at the other end thereof.

An anode of the diode D1b is connected to the node N1b, and a cathode thereof is grounded.

The resistance element 41 is connected to the node N1c at one end thereof, and is grounded at the other end thereof.

The operational amplifier AMP1 compares the voltages V1a and Vb with each other to thereby output a voltage based on the comparison result. That is, the operational amplifier AMP1 controls voltages to be applied to the gates of the transistors P1a, P1b, and P1c in such a manner that the voltages V1a and V1b become equal to each other.

In the configuration described above, the BGR circuit 201 outputs the voltage of the node N1c as an output voltage Vset1.

In the BGR circuit 201, currents I1 flowing through the node N1a, node N1b, and node N1c are equal to each other, and are expressed by the following formula (1).

I1=(V1b+(R11/R31)·VT·lnN)/R11 (1)

Here, R11 is a resistance value of the resistance element 11, and R31 is a resistance value of the resistance element 31. Further, VT is the thermoelectromotive force of the diode, and is expressed by the following formula (2).

VT=kT/q (2)

Here, k is the Boltzmann constant, T is an absolute temperature, and q is a charge amount of electrons.

From the formula (1), the voltage Vset1 is expressed by the following formula (3).

Vset1=(V1b+(R11/R31)·VT·lnN)·R41/R11 (3)

Here, R41 is a resistance value of the resistance element 41. Accordingly, by appropriately selecting a ratio between R11 and R41, it is possible to change the voltage of Vset1.

In the formula (3), V1b is a built-in potential of the diode, and has a negative temperature dependence, and hence by appropriately selecting the ratio R11/R31, it is possible to change the temperature characteristics of the voltage Vset1. More specifically, the temperature characteristics of the built-in potential of the diode is −2 [mV/° C.], and hence in order to make the voltage Vset1 has no temperature dependence, it is sufficient if the ratio R11/R31 is made to satisfy the following formula (4).

(R11/R31)·(k/q)·lnN=2 [mV] (4)

As a result, the BGR circuit 201 applies a constant voltage irrespective of the temperature (having no temperature dependence).

The BGR circuit 202 has the same configuration as the BGR circuit 201, and includes an operational amplifier AMP2, p-channel MOS transistors P2a, P2b, and P2c, resistance elements 12, 22, 32, and 42, N (N is an integer greater than or equal to 2) diodes D2a, and diode D2b. The transistors P2a, P2b, and P2c have the same transistor size. The diodes D2a, and the diode D2b have the same current-voltage characteristics. Further, the BGR circuit 202 outputs the voltage of the node N2c as an output voltage Vset2.

Further, in the BGR circuit 202 too, the above-mentioned formulae (1) to (3) are established as in the case of the BGR circuit 201. However, in the BGR circuit 202, the configuration is contrived in such a manner that the formula (5) is established in place of the formula (4).

(R12/R32)·(k/q)·lnN<2 [mV] (5)

Here, R12 is a resistance value of the resistance element 12, and R32 is a resistance value of the resistance element 32. As a result, the output voltage of the BGR circuit 202 has a negative temperature dependence.

Next, the voltage selection circuit 220 will be described below. The voltage selection circuit 220 is a circuit comparing the voltage Vset1 and voltage Vset2 with each other, and output the lower voltage as a set voltage Vset. The voltage selection circuit 220 includes two operational amplifiers AMP31 and AMP32, p-channel MOS transistors P31 and P32, and resistance element 61.

The operational amplifier AMP31 compares the voltage Vset1 and a voltage of a node N3 with each other, and outputs the voltage based on the comparison result. That is, the operational amplifier AMP31 controls the voltage to be applied to a gate of the transistor P31 in such a manner that the voltage Vset1 and the voltage of the node N3 become equal to each other.

The operational amplifier AMP32 compares the voltage Vset2 and the voltage of the node N3 with each other, and outputs the voltage based on the comparison result. That is, the operational amplifier AMP32 controls the voltage to be applied to a gate of the transistor P32 in such a manner that the voltage Vset2 and the voltage of the node N3 become equal to each other.

In each of the transistors P31 and P32, the voltage VDD is input to a source, and a drain is connected to the node N3. The resistance element 61 is connected between the node N3 and ground node. The voltage of the node N3 is output from the Vset generator 121 as the set voltage Vset.

For example, when the voltage Vset1 is lower than the voltage Vset2, the voltage of the node N3 becomes equal to the voltage Vset1, and the voltage Vset1 is output as the set voltage Vset. On the other hand, when the voltage Vset2 is lower than the voltage Vset1, the voltage of the node N3 becomes equal to the voltage Vset2, and the voltage Vset2 is output as the set voltage Vset.

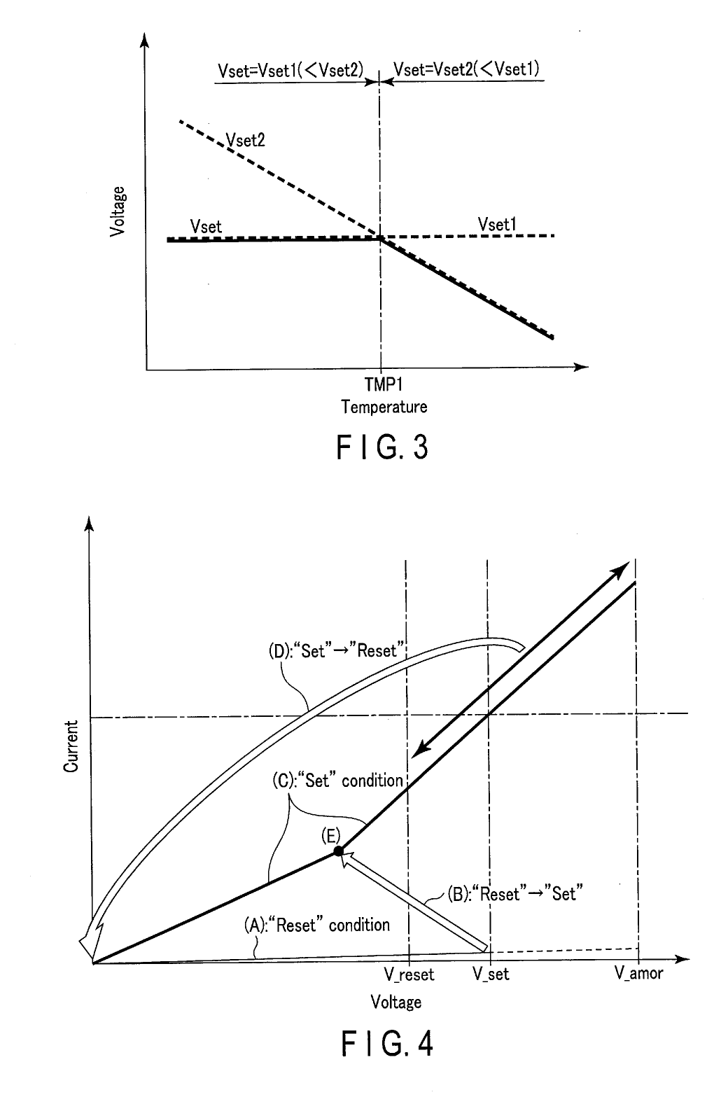

Accordingly, the temperature dependence of the output voltage Vset of the Vset generator 121 becomes as shown in FIG. 3. FIG. 3 is a graph showing the temperature dependence of the set voltage Vset. In FIG. 3, the graphs shown by broken lines are graphs of the voltages Vset1 and Vset2, and the graph shown by a solid line is a graph of the voltage Vset. In FIG. 3, in order to make the part at which the broken line and the solid line overlap each other easy to understand, the broken line and the solid line are drawn in parallel with each other. As shown in FIG. 3, in a range lower than or equal to a given temperature TMP1, the voltage Vset1 is output, and hence the voltage Vset has no temperature dependence. Conversely, in a range higher than the temperature TMP1, the voltage Vset2 is output, and hence the voltage Vset has a negative temperature dependence.

### 1.3 Write Operation

Next, a write operation in this embodiment will be described below. In this embodiment, bringing the variable resistance element VR from the reset state into the set state is defined as “0” data write, and bringing the variable resistance element VR from the set state into the reset state is defined as “1” data write. It should be noted that the definition of the “0” data and “1” data may be reversed.

First, the “0” data write will be described. The source-line driver 115 applies a voltage VSS (for example, 0 V) to a selected source line SL corresponding to the selected memory cell MC. In this state, the bit-line driver 112 applies a set voltage pulse to a selected bit line BL. The set voltage pulse is a voltage pulse realized by applying the set voltage Vset to the variable resistance element VR for a certain period (time Tset). At this time, a forward bias is applied to the diode DI of the selected memory cell MC, and a set current Iset flows from the selected bit line BL to the selected source line SL. Further, the variable resistance element VR carries out a phase change to be brought into the set state.

Next, the “1” data write will be described. As in the case of the “0” data write, the source-line driver 115 applies the voltage VSS (for example, 0 V) to the selected source line SL corresponding to the selected memory cell MC. In this state, the bit-line driver 112 applies a reset voltage pulse to the selected bit line BL. The reset voltage pulse is a voltage pulse realized by applying the reset voltage Vrst to the variable resistance element VR for a certain period (time Trst). At this time, a reset current Irst flows from the selected bit line BL to the selected source line SL. Further, the variable resistance element VR carries out a phase change to be brought into the reset state.

Then, the bit-line driver 112 applies the voltage VSS to the unselected bit lines BL. The source-line driver 115 applies a voltage higher than the voltage to be applied to the selected bit line BL to the unselected source lines SL. Thereby, a reverse bias is applied to the diodes DI of the unselected memory cells MC, and hence no currents flow through the unselected memory cells MC. Accordingly, in each of the variable resistance elements VR of the unselected memory cells MC, no phase change occurs, and no data is written.

It should be noted that it is sufficient if each of the set voltage pulse and the reset voltage pulse has a voltage and duration necessary for a phase change, and a relationship between the set voltage Vset and reset voltage Vrst, and a relationship between the time Tset and time Trst are not particularly limited.

Next, a relationship between the voltage (a potential difference between both ends of the variable resistance element VR) to be applied to the variable resistance element VR and phase change caused by the voltage application will be described below.

FIG. 4 is a graph showing the relationship between the voltage to be applied to the variable resistance element VR and phase change. First, the case where the set voltage pulse is applied to the variable resistance element VR will be described below. When the variable resistance element VR is in the reset state (high-resistance state) (line (A)), even if the applied voltage is increased, the current flowing through the variable resistance element VR is hardly increased. After the applied voltage reaches the voltage V_set, concomitantly with a decrease of the variable resistance element VR in resistivity, the current increases (line (B)), and the variable resistance element VR is brought into the set state (point (E)). The set voltage Vset has an optimum value. When the voltage is too low, a phase change does not occur, and when the voltage is too high, even if the variable resistance element VR is once brought into the set state, the element VR is returned to the reset state concomitantly with an increase in voltage.

Next, the case where a reset voltage pulse is applied to the variable resistance element VR will be described below. When the variable resistance element VR is in the set state (low-resistance state) (line (C)), a current larger than the reset state flows through the variable resistance element VR. When the voltage is lowered at the time at which the voltage has reached the minimum voltage necessary for causing a phase change to the reset state, the variable resistance element VR carries out a phase change to be brought into the reset state (line (D)).

### 1.4 Advantage of First Embodiment

When the configuration according to this embodiment is employed, it is possible to improve the reliability of the write operation. This advantage will be described below.

Although the iPCM has been proposed as a device by which low current consumption and low-voltage operation can be expected, and as a variable resistance type memory,. a method and circuit for optimizing the set voltage Vset with respect to a surrounding environmental temperature have not been proposed.

Regarding this, the inventors of the present application have found that the optimum set voltage of the iPCM differs depending on the surrounding environmental temperature. That is, the inventors have found that the set voltage does not have temperature dependence at temperatures lower than or equal to a certain temperature, and has a negative temperature dependence at temperatures higher than such temperature.

For example, when a given set voltage Vset is applied to the variable resistance element VR without taking the temperature dependence into consideration, there is the possibility of the variable resistance element VR not carrying out a phase change to the set state in a certain temperature range. That is, there is the possibility of erroneous write of “0” data being caused.

Thereupon, in this embodiment, the optimum temperature characteristics of the set voltage found in the iPCM are imparted to the output voltage of the Vset generator 121. More specifically, the Vset generator 121 includes the BGR circuit 201 having no temperature dependence and BGR circuit 202 having a negative temperature dependence. Further, by selecting a lower voltage from voltages output from these BGR circuits, and applying the selected lower voltage to the memory cell MC, it is possible for the Vset generator 121 to apply the optimum set voltage Vset corresponding to the temperature to the variable resistance element VR. Accordingly, the variable resistance element VR can carry out a phase change to the set state irrespective of the surrounding environmental temperature. As a result, it is possible to prevent erroneous write from being caused, and improve the reliability of the write operation.

Furthermore, this embodiment achieves the advantages as described above whether the number of the diodes D1a included in the BGR circuit 201 and the number of the diodes D2a included in the BGR circuit 202 are the same or not. That is, this embodiment achieves the advantages as described above, when the BGR circuit 201 and the BGR circuit 202 satisfy the formula (4) and the formula (5), respectively. More specifically, for example, in order to satisfy the formula (4) and the formula (5), the ratio R11/R31 and the ratio R12/R32 may be set when the number of diodes D1a and the number of diodes D2a are the same as N. Further, for example, in order to satisfy the formula (4) and the formula (5), the number of diodes D1a and the number of diodes D2a may be set.

### 2. Second Embodiment

A semiconductor storage device of a second embodiment will be described below. The second embodiment is an embodiment in which a BGR circuit having a negative temperature dependence is applied to the Irst generator 122 described in the first embodiment. In the following, only points different from the first embodiment will be described.

### 2.1 Configuration of Irst Generator

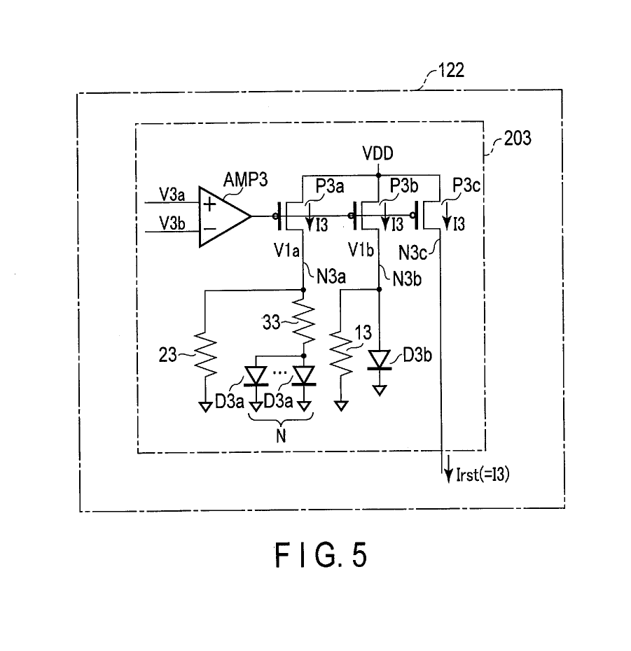

FIG. 5 is a circuit diagram of an Irst generator 122. The Irst generator 122 of this embodiment includes a BGR circuit 203. What makes the BGR circuit 203 different from the BGR circuits 201 and 202 is that the resistance element 41 (or the resistance element 42) is annulled, and current output is employed instead.

The BGR circuit 203 includes an operational amplifier AMPS, p-channel MOS transistors P3a, P3b, and P1c, resistance elements 13, 23, and 33, N (N is an integer greater than or equal to 2) diodes D3a, and diode D3b.

The transistors P3a, P3b, and P3c have the same transistor size.

The diodes D3a, and the diode D3b have the same current-voltage characteristics. Further, connection of each element is identical to the BGR circuits 201 and 202. Further, the Irst generator 122 outputs a current flowing through a node N3c as the reset current Irst.

Next, a relationship between the reset current Irst and surrounding environmental temperature will be described below.

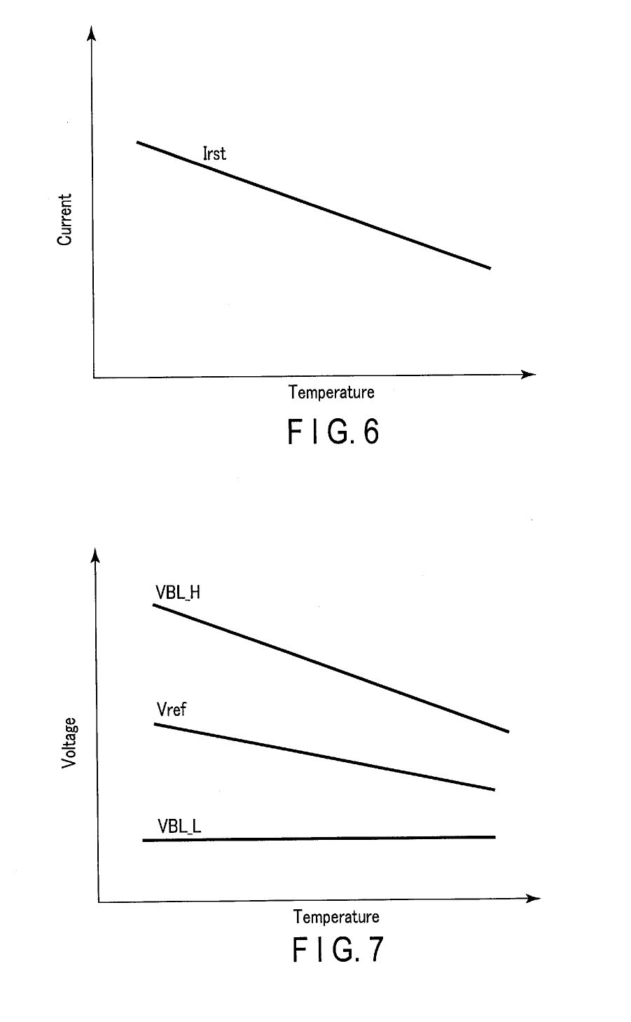

FIG. 6 is a graph showing temperature dependence of the reset current Irst. The reset current Irst in the iPCM has a negative temperature dependence. Accordingly, when the resistance values of the resistance elements 13 and 33 are assumed to be R13 and R33, a relationship of the following formula (5′) is established.

(R13/R33)·(k/q)·lnN<2 [mV] (5′)

Accordingly, in the BGR circuit 203, the ratio R13/R33 is set in such a manner that the reset current Irst has a negative temperature dependence.

### 2.2 Advantage of Second Embodiment

When the configuration according to this embodiment is employed, it is possible to improve the reliability of the write operation. This advantage will be described below.

The inventors of the present application have found that when a reset voltage pulse is to be applied to the variable resistance element VR, the reset current flowing through the variable resistance element VR has the optimum value depending on the surrounding environmental temperature. That is, the inventors have found that the reset current has a negative temperature dependence.

Accordingly, when the reset voltage pulse is to be applied to the variable resistance element VR, it is necessary to control the reset current Irst flowing through the variable resistance element VR according to the temperature.

For example, when a given reset current Irst is supplied to the variable resistance element VR without taking the temperature dependence into consideration, there is the possibility of the variable resistance element VR not carrying out a phase change to the reset state in a certain temperature range. That is, there is the possibility of erroneous write of “1” data being caused.

Thereupon, in this embodiment, the optimum temperature dependence of the reset current found in the iPCM is imparted to the output current of the Irst generator 122. More specifically, the Irst generator 122 includes the BGR circuit 203 having a negative temperature dependence. Further, by using the BGR circuit 203 as a current source circuit, it is possible for the Irst generator 122 to supply the optimum reset current Irst corresponding to the temperature to the variable resistance element VR. Accordingly, the variable resistance element VR can carry out a phase change to the reset state irrespective of the surrounding environmental temperature. As a result, it is possible to prevent erroneous write from being caused, and improve the reliability of the write operation.

### 3. Third Embodiment

A semiconductor storage device of a third embodiment will be described below. The third embodiment is an embodiment in which a BGR circuit having a negative temperature dependence is applied to the Vref generator 123 described in the first embodiment. In the following, only points different from the first and second embodiments will be described.

### 3.1 Configuration of Vref Generator

A Vref generator 123 of this embodiment includes a BGR circuit having a negative temperature dependence identical to the BGR circuit 202 described in connection with FIG. 2. Further, by this BGR circuit, a reference voltage Vref having a negative temperature dependence is output. It should be noted that a resistance value of each resistance element of the BGR circuit included in the Vref generator 123 is set according to the temperature characteristics required of the reference voltage Vref, and hence the resistance value may be different from the BGR circuit 202 if the resistance value satisfies the relationship of the formula (5).

### 3.2 Read Operation

Next, a read operation in this embodiment will be described below. The read operation is carried out by applying a voltage (<Vrst, <Vset) of such a degree that the variable resistance element VR does not carry out a phase change to a selected bit line BL in a state where a voltage VSS is applied to a selected source line SL, and sensing a change in voltage of the bit line BL attributable to a difference in resistance value between variable resistance elements VR by using the sense amplifier 113.

### 3.2.1 Voltage of Bit Line in Read Operation

A voltage of a bit line in a read operation will be described below. When “1” data has been written to the memory cell MC, the variable resistance element VR is in the high-resistance state, and hence a current flowing through the memory cell MC is small. A voltage of the bit line at this time is assumed to be VBL_H. On the other hand, when “0” data has been written to the memory cell MC, the variable resistance element VR is in the low-resistance state, and hence a current larger than in the case of the high-resistance state flows through the memory cell MC. The voltage of the bit line BL becomes lower than in the case where “1” data has been written to the memory cell MC. The voltage of the bit line BL at this time is assumed to be VBL_L. Further, a reference voltage used to carry out comparison of the voltage of the bit line BL in the sense amplifier 113 in the read operation is assumed to be Vref, and is provided in such a manner that the reference voltage Vref satisfies a relationship of VBL_L<Vref<VBL_H.

The sense amplifier 113 compares the reference voltage Vref and voltage of the bit line BL with each other and, when the voltage of the bit line BL is higher than the reference voltage Vref (VBL_H>Vref), reads the “1” data. On the other hand, when the voltage of the bit line BL is lower than the reference voltage Vref (VBL_L<Vref), the sense amplifier 113 reads the “0” data.

### 3.2.2 Temperature Dependence of Read Operation

FIG. 7 is a graph showing temperature dependence of the voltage of the bit line BL, and reference voltage Vref in the read operation. As shown in FIG. 7, the voltage VBL_H has a negative temperature dependence. Further, the voltage VBL_L hardly has any temperature dependence. Conversely, the reference voltage Vref has a negative temperature dependence in such a manner that the reference voltage Vref is between the voltage VBL_H and voltage VBL_L. More specifically, the magnitude |dVref/dT| of the gradient of the reference voltage Vref to the temperature is made smaller than the magnitude |dVBL_H/dT| of the gradient of the voltage VBL_H to the temperature.

### 3.3 Advantage of Third Embodiment

When the configuration according to this embodiment is employed, it is possible to improve the reliability of the read operation. This advantage will be described below.

The inventors of the present application have found that the temperature dependence of the resistance value differs between the case where the variable resistance element VR is in the set state in the read operation, and the case where the variable resistance element VR is in the reset state in the read operation. That is, the inventors have found that although the resistance value of the variable resistance element VR in the reset state has a negative temperature dependence, the resistance value of the variable resistance element VR in the set state hardly has any temperature dependence.

For example, when a reference voltage Vref necessary for read is applied without taking the temperature dependence into consideration, there is the possibility of erroneous read of data being caused owing to the fact that a voltage difference between the voltage Vref and voltage VBL_H almost disappears in a certain temperature range or the voltage Vref becomes higher than the voltage VBL_H, and the like.

Thereupon, in this embodiment, the optimum temperature characteristics of the reference voltage Vref found in the iPCM are imparted to the output voltage of the Vref generator 123. More specifically, the Vref generator 123 includes a BGR circuit having a negative temperature dependence. Thereby, it is possible for the Vref generator 123 to apply an optimum reference voltage Vref corresponding to the temperature dependence of the voltage VBL_H and voltage VBL_L to the sense amplifier 113. Accordingly, it is possible to prevent erroneous read from being caused, and improve the reliability of the read operation.

### 4. Fourth Embodiment

A semiconductor storage device of a fourth embodiment will be described below. What makes the fourth embodiment different from the first to third embodiments is that a voltage Vset2 having a negative temperature dependence is generated by using a current obtained by combining a current from a BGR circuit having no temperature dependence and a current from a BGR circuit having a negative temperature dependence with each other. Hereinafter, only points different from the first embodiment will be described.

### 4.1 Configuration of Vset Generator

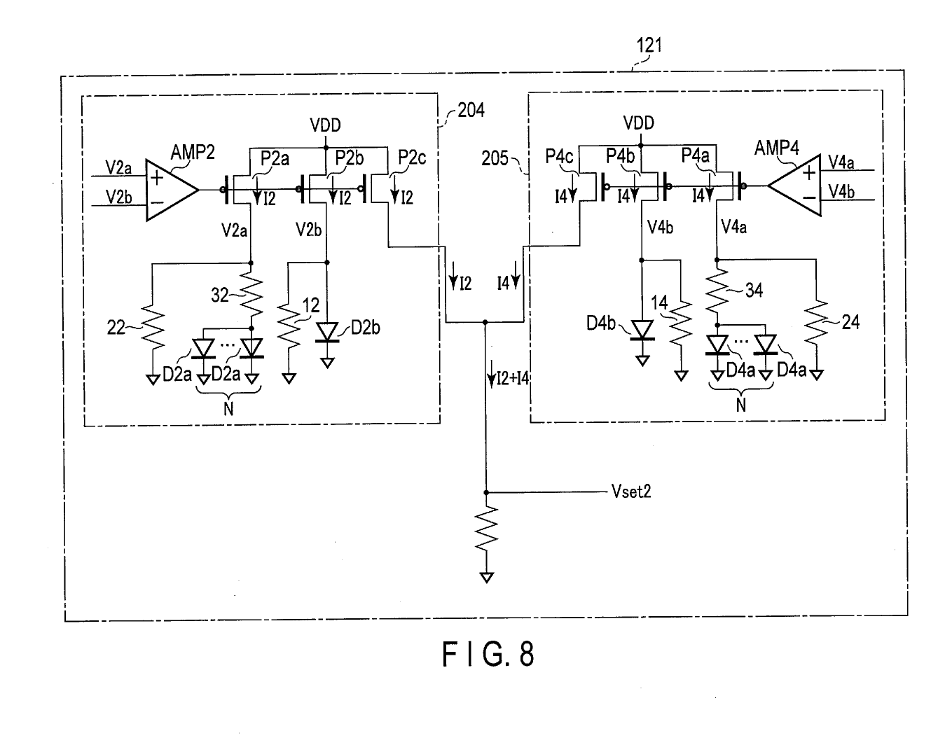

FIG. 8 is a circuit diagram of a Vset generator 121 in this embodiment. The Vset generator 121 of this embodiment includes BGR circuits 204 and 205.

The BGR circuit 204 is a circuit obtained by annulling the resistance element 42 in the BGR circuit 202 described in connection with FIG. 2, and a current I2 is output therefrom. The current I2 has a negative temperature dependence.

The BGR circuit 205 has a configuration identical to the BGR circuit 204, and includes an operational amplifier AMP4, p-channel MOS transistors P4a, P4b, and P4c, resistance elements 14, 24, and 34, N (N is an integer greater than or equal to 2) diodes D4a, and diode D4b.

The transistors P4a, P4b, and P4c have the same transistor size.

The diodes D4a, and the diode D4b have the same current-voltage characteristics.

Assuming the resistance values of the resistance elements 14 and 34 to be R14 and R34, a relationship of the following formula (4′) is established.

(R14/R34)·(k/q)·lnN=2 [mV] (4′)

Accordingly, in the BGR circuit 205, the ratio of R14/R34 is set in such a manner that the current I4 has no temperature dependence.

Further, the voltage Vset2 is generated by using a current obtained by adding the current I4 to the current I2.

### 4.2 Advantage of Fourth Embodiment

When the configuration according to this embodiment is employed, advantages identical to the first embodiment described previously are obtained.

Further, in this embodiment, by adding an output current of the BGR circuit having the negative temperature dependence to an output current of the BGR circuit having no temperature dependence, it is possible to more easily generate a current having required temperature characteristics and a required current value. Hereinafter, specific descriptions will be given.

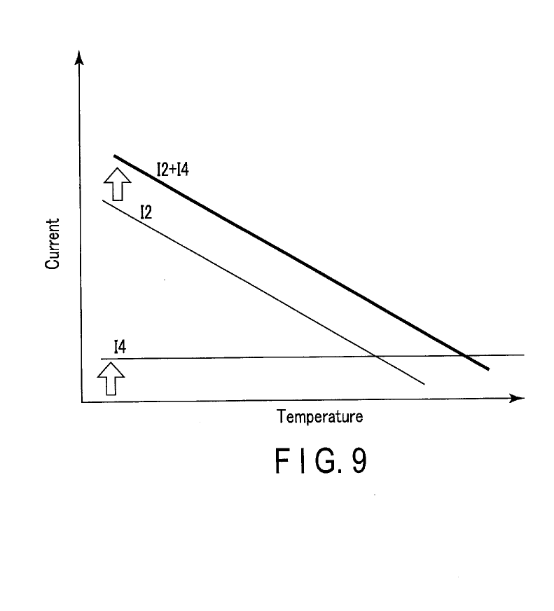

FIG. 9 is a graph showing temperature dependence of the output current I2 of the BGR circuit 204 and the output current I4 of BGR circuit 205. For example, when the gradient of the temperature characteristics of the output current I2 is optimized by adjusting the ratio of the internal resistance values (R12/R32), not only the gradient, but also the overall current value are shifted to be deviated from the optimum values in some cases.

Conversely, in this embodiment, first the gradient of the temperature characteristics is optimized by using the current I2 having the negative temperature dependence, and then the current I4 having no temperature dependence is added to the current I2, whereby both the gradient and the overall current value are optimized. Accordingly, it is possible to obtain an output current having required temperature characteristics and a required current value. By using this output current, it becomes easy to optimize the negative temperature dependence and voltage value of the voltage Vset2. As a result, it is possible to improve the reliability of the write operation.

It should be noted that the configuration according to this embodiment can be applied to the Irst generator 122 of the second embodiment. Thereby, it becomes easy to optimize the reset current Irst. Accordingly, the Irst generator 122 can supply an optimum reset current Irst corresponding to the temperature to the variable resistance element VR. As a result, by virtue of the advantages of the second embodiment and this embodiment, it is possible to improve the reliability of the write operation.

Furthermore, the configuration according to this embodiment can be applied to the Vref generator 123 of the third embodiment. Thereby, it becomes easy to optimize the reference voltage Vref. Accordingly, the Vref generator 123 can apply an optimum reference voltage Vref corresponding to the temperature to the sense amplifier 113. As a result, by virtue of the advantages of the third embodiment and this embodiment, it is possible to improve the reliability of the read operation.

Furthermore, this embodiment achieves the advantages as described above whether the number of the diodes D2a included in the BGR circuit 204 and the number of the diodes D4a included in the BGR circuit 205 are the same or not. That is, this embodiment achieves the advantages as described above, when the BGR circuit 204 and the BGR circuit 205 satisfy the formula (4′) and the formula (5), respectively. More specifically, for example, in order to satisfy the formula (4′) and the formula (5), the ratio R12/R32 and the ratio R14/R34 may be set when the number of diodes D2a and the number of diodes D4a are the same as N. Further, for example, in order to satisfy the formula (4′) and the formula (5), the number of diodes D2a and the number of diodes D4a may be set.

### 5. Fifth Embodiment

A semiconductor storage device of a fifth embodiment will be described below. What makes the fifth embodiment different from the first to fourth embodiments is that each of the BGR circuits includes a switch circuit, and the switch circuits are controlled according to the magnitudes of an output voltage of an operational amplifier AMP1 and output voltage of an operational amplifier AMP2. Hereinafter, only points different from the first embodiment will be described.

### 5.1 Configuration of Vset Generator

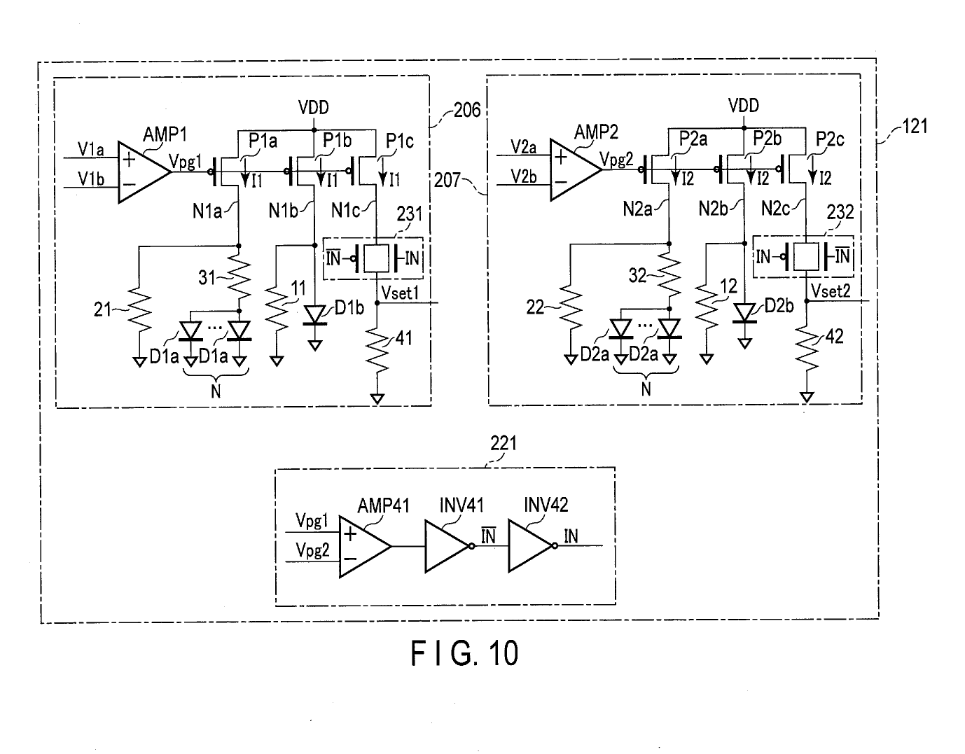

FIG. 10 is a circuit diagram of a Vset generator 121 in this embodiment. The Vset generator 121 of this embodiment includes BGR circuits 206 and 207, and voltage comparison circuit 221.

The BGR circuit 206 is a circuit obtained by providing a switch circuit 231 at the node N1c in the BGR circuit 201 described in connection with FIG. 2. The switch circuit 231 includes an n-channel MOS transistor and p-channel MOS transistor which are connected in parallel with each other, in which a signal IN is input to a gate of the n-channel MOS transistor and a signal /IN is input to a gate of the p-channel MOS transistor.

The BGR circuit 207 is a circuit obtained by providing a switch circuit 232 at the node N2c in the BGR circuit 202 described in connection with FIG. 2. The switch circuit 232 includes an n-channel MOS transistor and p-channel MOS transistor which are connected in parallel with each other, in which a signal /IN is input to a gate of the n-channel MOS transistor and a signal IN is input to a gate of the p-channel MOS transistor. Further, the transistor sizes of the six transistors P1a to P1c, and P2a to P2c are identical.

The voltage comparison circuit 221 includes an operational amplifier AMP41, and inverters INV41 and INV42. In the operational amplifier AMP41, a voltage Vpg1 of an output terminal of the operational amplifier AMP1 of the BGR circuit 206 is input to a non-inverting input terminal, a voltage Vpg2 of an output terminal of the operational amplifier AMP2 of the BGR circuit 207 is input to an inverting input terminal, and the inverters INV41 and INV42 are connected to an output terminal in series. An output of the inverter INV41 becomes the signal /IN, and an output of the inverter INV42 becomes the signal IN.

### 5.2 Output Operation of Set Voltage Vset

Next, output of the set voltage Vset in this embodiment will be specifically described below. First, when the voltage Vset1 is lower than the voltage Vset2, i.e., when the current I1 is smaller than the current I2, the voltage Vpg1 becomes higher than the voltage Vpg2. Accordingly, the output of the operational amplifier AMP41 is brought to the “H” level, the output of the inverter INV41 is brought to the “L” level, and the output of the inverter INV42 is brought to the “H” level. That is, the signal IN is brought to the “H” level, and the signal /IN is brought to the “L” level, and hence the switch circuit 231 is brought into the on-state and the switch circuit 232 is brought into the off-state. As a result, the voltage Vset1 is output as the set voltage Vset.

On the other hand, when the voltage Vset1 is higher than the voltage Vset2, the voltage Vpg1 becomes lower than the voltage Vpg2, and hence the signal IN is brought to the “L” level, and the signal /IN is brought to the “H” level. Accordingly, the switch circuit 231 is brought into the off-state, and the switch circuit 232 is brought into the on-state. As a result, the voltage Vset2 is output as the set voltage Vset. In this manner, it is possible at all times to output the lower of the voltage Vset1 and voltage Vset2 as the set voltage Vset.

### 5.3 Advantage of Fifth Embodiment

One of the voltage Vset1 and voltage Vset2 may be selected by means of the configuration according to this embodiment.

Furthermore, in this embodiment, the BGR circuit includes a switching circuit. Therefore, the voltage comparison circuit can be simply configured by an operational amplifier and two inverters. An increase in the chip area can therefore be suppressed.

Furthermore, this embodiment achieves the advantages as described above whether the number of the diodes D1a included in the BGR circuit 206 and the number of the diodes D2a included in the BGR circuit 207 are the same or not. That is, this embodiment achieves the advantages as described above, when the BGR circuit 206 and the BGR circuit 207 satisfy the formula (4) and the formula (5), respectively. More specifically, for example, in order to satisfy the formula (4) and the formula (5), the ratio R11/R31 and the ratio R12/R32 may be set when the number of diodes D1a and the number of diodes D2a are the same as N. Further, for example, in order to satisfy the formula (4) and the formula (5), the number of diodes D1a and the number of diodes D2a may be set.

### 6. Sixth Embodiment

A semiconductor storage device of a sixth embodiment will be described below. What makes the sixth embodiment different from the first to fifth embodiments is that a node used by each BGR circuit to compare voltages is further provided. Hereinafter, only points different from the first to fifth embodiments will be described.

### 6.1 Configuration of Vset Generator

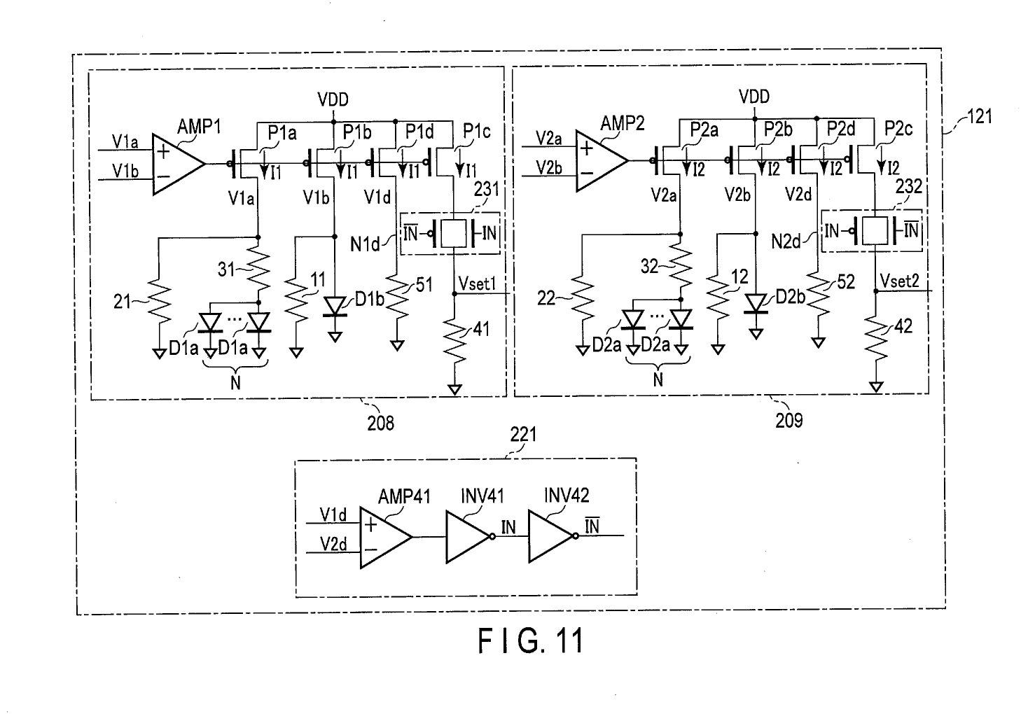

FIG. 11 is a circuit diagram of a Vset generator 121 in this embodiment. The Vset generator 121 of this embodiment includes BGR circuits 208 and 209, and voltage comparison circuit 221.

The BGR circuit 208 is a circuit obtained by further providing a p-channel MOS transistor P1d and resistance element 51 in the BGR circuit 206 described in connection with FIG. 10. In the transistor P1d, a gate thereof is connected to an output terminal of an operational amplifier AMP1, a voltage VDD is input to a source thereof, and a drain thereof is connected to a node N1d. The resistance element 51 is connected between the node N1d and ground node.

The BGR circuit 209 is a circuit obtained by further providing a p-channel MOS transistor P2d and resistance element 52 in the BGR circuit 207 described in connection with FIG. 10. Connections of the transistor P2d and resistance element 52 are identical to the BGR circuit 208. Further, the sizes of the eight transistors P1a to P1d and P2a to P2d are identical, and the resistance values of the resistance elements 51 and 52 are identical.

In the voltage comparison circuit 221 in this embodiment, a voltage V1d of a node N1d of the BGR circuit 208 is input to a non-inverting input terminal, and a voltage V2d of a node N2d of the BGR circuit 209 is input to an inverting input terminal. Further, an output of the inverter INV41 becomes a signal IN, and an output of the inverter INV42 becomes a signal /IN.

### 6.2 Output Operation of Set Voltage Vset

Next, output of the voltage Vset in this embodiment will be specifically described below. First, when the voltage Vset1 is lower than the voltage Vset2, i.e., when the current I1 is smaller than the current I2, the voltage V1d becomes lower than the voltage V2d because the resistance values of the resistance element 51 and resistance element 52 are identical. Accordingly, the output of the operational amplifier AMP41 is brought to the “L” level, the output of the inverter INV41 is brought to the “H” level, and the output of the inverter INV42 is brought to the “L” level. That is, the signal IN is brought to the “H” level and the signal /IN is brought to the “L” level, and hence the switch circuit 231 is brought into the on-state and the switch circuit 232 is brought into the off-state. As a result, the voltage Vset1 is output as the set voltage Vset.

On the other hand, when the voltage Vset1 is higher than the voltage Vset2, the voltage V1d becomes higher than the voltage V2d, and hence the signal IN is brought to the “L” level and the signal /IN is brought to the “H” level. Accordingly, the switch circuit 231 is brought into the off-state and the switch circuit 232 is brought into the on-state. As a result, the voltage Vset2 is output as the set voltage Vset. In this manner, it is possible at all times to output the lower of the voltage Vset1 and voltage Vset2 as the set voltage Vset.

### 6.3 Advantage of Sixth Embodiment

One of the voltage Vset1 and voltage Vset2 may be selected by means of the configuration according to this embodiment.

Furthermore, in this embodiment, the BGR circuit includes a node used when the voltage comparison circuit compares voltages. Therefore, it is possible to decrease the influence of the noise occurred by the voltage comparison circuit on the output of BGR circuit. The Vset generator can output a low noise voltage Vset.

Furthermore, this embodiment achieves the advantages as described above whether the number of the diodes D1a included in the BGR circuit 208 and the number of the diodes D2a included in the BGR circuit 209 are the same or not. That is, this embodiment achieves the advantages as described above, when the BGR circuit 208 and the BGR circuit 208 satisfy the formula (4) and the formula (5), respectively. More specifically, for example, in order to satisfy the formula (4) and the formula (5), the ratio R11/R31 and the ratio R12/R32 may be set when the number of diodes D1a and the number of diodes D2a are the same as N. Further, for example, in order to satisfy the formula (4) and the formula (5), the number of diodes D1a and the number of diodes D2a may be set.

### 7. Modification Examples, And the Like

The semiconductor storage device according to the aforementioned embodiments includes a first memory cell (MC in FIG. 1), first bit line (BL in FIG. 1) connected to the first memory cell, and first circuit (121 in FIG. 1) applying a first voltage (Vset in FIG. 3) to the first bit line in a write operation for the first memory cell. The first voltage has no temperature dependence at temperatures lower than or equal to a first temperature, and has a negative temperature dependence when the temperature is higher than the first temperature.

By applying the embodiments, it is possible to provide a semiconductor storage device capable of improving the reliability. It should be noted that the embodiment is not limited to the aforementioned embodiments, and may be variously modified.

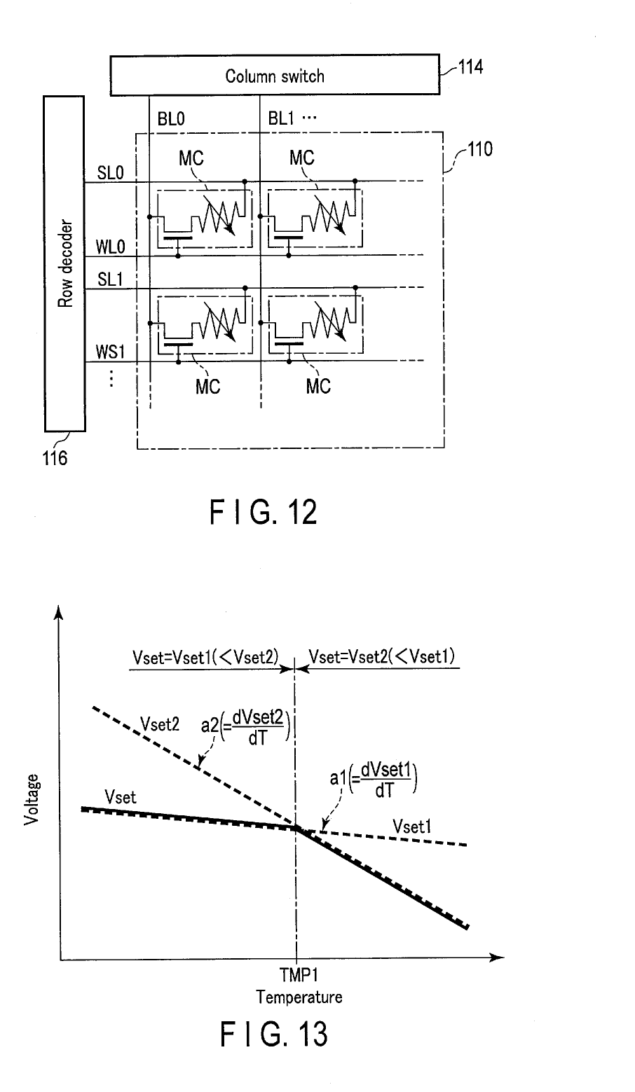

For example, in each of the aforementioned embodiments, different memory cells may be used. Such an example is shown in FIG. 12.

FIG. 12 is a block diagram showing a modification example of the memory cell array 110. Memory cells arranged on the same column are connected to a certain bit line BLk (k is an integer greater than or equal to 0) as a common connection. Memory cells arranged on the same row are connected to a certain source line SLm (m is an integer greater than or equal to 0), and a certain word line WLm as a common connection. The memory cell MC includes a variable resistance element VR and transistor connected in series. The variable resistance element VR is connected to a source line SL at one end thereof and is connected to one of a source and drain of the transistor at the other end thereof. The transistor functions as a transfer gate transistor, a gate thereof is connected to a word line WL, and other of a source and drain thereof is connected to a bit line BL. The bit line BL is connected to a column switch 114, and the source line SL and the word line WL are connected to a row decoder 116. In the write or read operation, the row decoder 116 applies a voltage VSS to, for example, all the source lines SL, brings a selected word line WL to the “H” level, and brings a transistor of a memory cell MC of a target row into the on-state. In this state, in the memory cell MC, writing and reading of data are carried out through a corresponding bit line BL.

Furthermore, in each of the aforementioned embodiments, although a case where the set voltage Vset has no temperature dependence at temperatures lower than or equal to a certain temperature and has negative temperature dependence at temperatures higher than the temperature has been described, the temperature characteristics of the BGR circuit may be appropriately changed according to the characteristics of the variable resistance element VR. Such an example is shown in FIG. 13.

FIG. 13 is a graph showing a modification example of temperature dependence of the set voltage. In the example of FIG. 13, the set voltage Vset has two types of negative temperature dependence differing from each other according to the temperature. More specifically, a voltage Vset1 and a voltage Vset2 each have a negative temperature dependence, and the absolute value of a gradient a1 (=dVset1/dT<0) of the voltage Vset1 is smaller than the absolute value of a gradient a2 (=dVset2/dT<0) of the voltage Vset2 (|a1|<|a2|). In this case, it is sufficient if the ratio R11/R31 and the ratio R12/R32 are set in such a manner that in, for example, the formula (4), the expression is changed to (R11/R31)·(k/q)·lnN<2 [mV] and (R12/R32)·(k/q)·lnN<2 [mV], and the relationship (R11/R31)>(R12/R32) is satisfied.

Further, for example, the voltage Vset1 may have a positive temperature dependence. In this case, it is sufficient if the ratio R11/R31 satisfying the relationship (R11/R31)·(k/q)·lnN>2 [mV] in the formula (4) is set. Further, for example, when the variable resistance element VR has three or more types of temperature dependence according to the temperature, the Vset generator 121 may include three or more BGR circuits corresponding to the types of temperature dependence. Regarding the reset current Irst and reference voltage Vref, the number of BGR circuits and their temperature characteristics may be appropriately changed according to the characteristics of the variable resistance element VR.

Furthermore, the BGR circuits of the aforementioned embodiments are only examples, and BGR circuits of different circuit configurations may also be used.

Furthermore, in the aforementioned embodiments, although p-channel MOS transistors have been used in the BGR circuits or in the voltage selection circuit 220, n-channel MOS transistors may also be used.

Furthermore, in each of the BGR circuits of the aforementioned embodiments, the number of diodes connected in parallel may be different in each BGR circuit.

Furthermore, each of the aforementioned embodiments may be separately implemented, and a plurality of embodiments may be combined with each other. For example, only the Irst generator in the aforementioned embodiment may be applied, and the aforementioned embodiment may not be applied to the Vset generator and Vref generator. Further, for example, only the Irst generator and the Vrst generator in the aforementioned embodiment may be applied, and the aforementioned embodiment may not be applied to the Vset generator.

Furthermore, in the aforementioned embodiments, although a description has been made by taking the case where the temperature characteristics of the built-in potential of the diode correspond to −2 [mV/° C.] as an example, the value of the temperature characteristics is not limited to this value, and various values may be employed according to the characteristics of the diode. Further, in the formula (4) described previously, it is sufficient if the following condition is satisfied.

(R11/R31)·(k/q)·lnN=(dV1b/dT)

However, the formula (4) does not necessarily require strict coincidence, and allows an error of a certain degree. That is, even when the value on the left-hand side of the formula (4) differs from the value on the right-hand side, the difference is allowed as an error if the error is within a range in which a normal operation of the iPCM can be obtained. Naturally, the range within which the operation is regarded as a normal operation may be appropriately changed for each product or the like.

The aforementioned embodiments are also applicable to a phase change random access memory (PRAM or PCM (phase change memory)), resistance random access memory (ReRAM), ferroelectric NAND-type memory (FeNAND), and magnetic random access memory (MRAM). Furthermore, the aforementioned embodiments are applicable to various types of storage devices requiring a voltage having a positive or negative temperature dependence.

Furthermore, the terms “connect” and “couple” in the aforementioned embodiments also include a state where a connection is indirectly made with the intervention of something such as a transistor, resistor or the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a first memory cell;
a first bit line coupled to the first memory cell; and
a first circuit applying a first voltage to the first bit line in a write operation for the first memory cell,
wherein the first voltage has no temperature dependence at temperatures lower than or equal to a first temperature, and has a negative temperature dependence at temperatures higher than the first temperature.

2. The device according to claim 1, wherein the first circuit includes:
a first voltage generator generating a second voltage which has no temperature dependence; and
a second voltage generator generating a third voltage which has negative temperature dependence, and
the first circuit applies the lower of the second voltage and the third voltage as the first voltage in the write operation.

3. The device according to claim 1, wherein the first memory cell includes a variable resistance element, and
the first voltage is applied to the first memory cell when a state of the variable resistance element is changed from a reset state to a set state.

4. The device according to claim 3, wherein
the variable resistance element is an interfacial phase change memory element (iPCM element, or a super lattice phase-change element).

5. The device according to claim 2, wherein the first voltage generator includes a first bandgap reference (BGR) circuit generating the second voltage, and
the second voltage generator includes a second BGR circuit generating the third voltage.

6. The device according to claim 2, wherein the first circuit further includes a voltage selection circuit selecting the lower of the second voltage and the third voltage,
the voltage selection circuit includes:
first and second transistors of a first conductivity type in which a power-supply voltage is applied to sources, and drains are coupled to a first interconnect as common connection;
a first operational amplifier comparing the second voltage with a voltage of the first interconnect, and applying a voltage corresponding to the comparison result to a gate of the first transistor;
a second operational amplifier comparing the third voltage with the voltage of the first interconnect, and applying a voltage corresponding to the comparison result to a gate of the second transistor; and
a first resistance element coupled between the first interconnect and a ground node, and
the voltage selection circuit outputs the voltage of the first interconnect as the first voltage.

7. The device according to claim 2, wherein the second voltage generator includes:
a first BGR circuit generating a first current which has no temperature dependence; and
a second BGR circuit generating a second current which has a negative temperature dependence, and
the second voltage generator generates the third voltage on the basis of the sum of the first current and the second current.

8. The device according to claim 5, wherein the first BGR circuit includes:
a first transistor of a first conductivity type in which a power-supply voltage is applied to a source, and a drain is coupled to a first interconnect;
a second transistor of the first conductivity type in which the power-supply voltage is applied to a source, and a drain is coupled to a second interconnect;
a third transistor of the first conductivity type in which the power-supply voltage is applied to a source, and a drain is coupled to a third interconnect;
a first operational amplifier comparing a voltage of the first interconnect with a voltage of the second interconnect, and applying a fourth voltage corresponding to the comparison result to gates of the first to third transistors;
a first diode in which an anode is coupled to the first interconnect, and a cathode is coupled to a ground node;
N (N is an integer greater than or equal to 2) second diodes in which cathodes are coupled to the ground node and anodes are coupled to each other as a common connection;
a first resistance element coupled between the first interconnect and the ground node;
a second resistance element coupled between the second interconnect and the ground node;
a third resistance element coupled between the third interconnect and the ground node; and
a fourth resistance element coupled between the second interconnect and the anodes of the N second diodes, and
the first BGR circuit outputs a voltage of the third interconnect as the second voltage.

9. The device according to claim 8, wherein, when a temperature characteristics value of a built-in potential of the second diode is −2 [mV/° C.],
a resistance value of the first resistance element is assumed to be R1, and
a resistance value of the fourth resistance element is assumed to be R3,
the following relationship is established:
(R1/R3)·(k/q)·lnN=2 [mV],
wherein k is a Boltzmann constant and q is a charge amount of electrons.

10. The device according to claim 8, wherein the second BGR circuit includes:
a fourth transistor of the first conductivity type in which the power-supply voltage is applied to a source, and a drain is coupled to fourth interconnect;
a fifth transistor of the first conductivity type in which the power-supply voltage is applied to a source, and a drain is coupled to fifth interconnect;
a sixth transistor of the first conductivity type in which the power-supply voltage is applied to a source, and a drain are coupled to sixth interconnect;
a second operational amplifier comparing a voltage of the fourth interconnect with a voltage of the fifth interconnect, and applying a fifth voltage corresponding to the comparison result to gates of the fourth to sixth transistors;
a third diode in which an anode is coupled to the fourth interconnect and a cathode is coupled to the ground node;
M (M is an integer greater than or equal to 2) fourth diodes in which cathodes are coupled to the ground node and anodes are coupled to each other as a common connection;
a fifth resistance element coupled between the fourth interconnect and the ground node;
a sixth resistance element coupled between the fifth interconnect and the ground node;
a seventh resistance element coupled between the sixth interconnect and the ground node; and
an eighth resistance element coupled between the fifth interconnect and the anodes of the M fourth diodes, and
the second BGR circuit outputs a voltage of the sixth interconnect as the third voltage.

11. The device according to claim 10, wherein, when a temperature characteristics value of a built-in potential of the fourth diode is −2 [mV/° C.],
a resistance value of the fourth resistance element is assumed to be R1, and
a resistance value of the sixth resistance element is assumed to be R3,
the following relationship is established:
(R1/R3)·(k/q)·lnM<2 [mV]
wherein k is a Boltzmann constant and q is a charge amount of electrons.

12. The device according to claim 10, wherein the first circuit compares the fourth voltage with the fifth voltage, then,
when the fourth voltage is higher than the fifth voltage, applies the second voltage as the first voltage and,
when the fourth voltage is lower than the fifth voltage, applies the third voltage as the first voltage.

13. The device according to claim 10, wherein the first voltage generator further includes:
a seventh transistor of the first conductivity type in which the power-supply voltage is applied to a source, the fourth voltage is applied to a gate, and a drain is coupled to a seventh interconnect; and
a ninth resistance element coupled between the seventh interconnect and the ground node,
the second voltage generator further includes:
an eighth transistor of the first conductivity type in which the power-supply voltage is applied to a source, the fifth voltage is applied to a gate, and a drain is coupled to an eighth interconnect; and
a tenth resistance element coupled between the eighth interconnect and the ground node, and
the first circuit compares a voltage of the seventh interconnect with a voltage of the eighth interconnect, then,
when the voltage of the seventh interconnect is lower than the voltage of the eighth interconnect, applies the second voltage as the first voltage and,
when the voltage of the seventh interconnect is higher than the voltage of the eighth interconnect, applies the third voltage as the first voltage.

14. A semiconductor storage device comprising:
a first memory cell;
a first bit line coupled to the first memory cell; and
a first circuit applying a first current which has a negative temperature dependence to the first bit line in a write operation for the first memory cell.

15. The device according to claim 14, wherein the first memory cell includes a variable resistance element, and
the first current flows through the first memory cell when the state of the variable resistance element is changed from the set state to the reset state.

16. The device according to claim 15, wherein the variable resistance element is an interfacial phase change memory element (iPCM element, or a super lattice phase-change element).

17. The device according to claim 14, wherein the first circuit includes:
a first BGR circuit generating a second current which has no temperature dependence; and
a second BGR circuit generating a third current which has a negative temperature dependence, and
the first circuit makes the sum of the second current and the third current as the first current.

18. A semiconductor storage device comprising:
a first memory cell;
a first bit line coupled to the first memory cell;
a sense amplifier coupled to the first bit line; and
a first circuit applying a first reference voltage which has a negative temperature dependence to the sense amplifier in a reading operation for the first memory cell.

19. The device according to claim 18, wherein the first memory cell includes a variable resistance element, and
in the read operation for the first memory cell, the first reference voltage is lower than a voltage of the first bit line at the time at which the variable resistance element is in the reset state, and is higher than the voltage of the first bit line at the time at which the variable resistance element is in the set state.

20. The device according to claim 19, wherein the variable resistance element is an interfacial phase change memory element (iPCM element, or a super lattice phase-change element).
